(19) United States
(12) Patent Application Publication
(10) Pub. No.: US 2002/0149297 A1
(43) Pub. Date: Oct. 17, 2002

(54) Piezoelectric element

(76) Inventors: Takashi Yamamoto, Chiryu-city (JP); Atsuhiro Sumiya, Hekinan-city (JP); Hitoshi Shindo, Okazaki-city (JP); Eturo Yasuda, Okazaki-city (JP); Shigehiko Sugiura, Nishio-city (JP)

Correspondence Address: Nixon & Vanderhye P.C., 8th Floor, 1100 North Glebe Road, Arlington, VA, 22201-4714, US

(21) Appl. No.: 10/119,956

(22) Filed: Apr. 11, 2002

(30) Foreign Application Priority Data
Apr. 12, 2001 (JP) 2001-114279

(51) Int. Cl. H01L 41/083

(52) U.S. Cl. 310/328

(57) ABSTRACT

A piezoelectric element having a structure capable of suppressing deformation during the fabrication thereof is disclosed. The piezoelectric element comprises a drive portion 101 including a plurality of ceramic layers 11 of a piezoelectric ceramic, a plurality of internal electrode layers 2 formed of a base metal as a main component for supplying electricity to the ceramic layers 11, and a dummy portion 103 formed at least on one end surface of the ceramic layers 11 of the drive portion 101 along the direction of stacking thereof, the ceramic layers 11 and the internal electrode layers 2 being stacked alternately. The dummy portion 103 is composed of ceramic and has at least one dummy electrode layer 3 of the same material as the internal electrode layers 2.

### BACKGROUND OF THE INVENTION

1. Field of the Invention

The present invention relates to a stack-type piezoelectric element comprising internal electrode layers of a base metal.

2. Description of the Related Art

A piezoelectric element comprising a plurality of layers of piezoelectric ceramic and a plurality of internal electrode layers stacked alternately can be used as an actuator, a capacitor, etc. In the prior art, the piezoelectric element comprises internal electrode layers including a precious metal, such as palladium, having a high corrosion resistance as a main component, and is fabricated by sintering a stack of ceramic layers and internal electrode layers in an air environment.

On the other hand, an attempt has been made to use a base metal for the internal electrode layers to reduce the cost of the piezoelectric element.

In the case where a base metal is used as a main component of the internal electrode layers, it is necessary to bake it in a reducing environment with a low oxygen concentration in order to prevent oxidization. A specific method is disclosed in, for example, Japanese Unexamined Patent Publication No. 5-82387.

In the piezoelectric element described above, an undriven dummy portion composed of a ceramic layer may be provided at each end of a drive portion including ceramic layers and internal electrode layers stacked alternately. In the case where the drive portion and the dummy portions in stack are sintered in a reduction environment, the base metal component of each of the internal electrode layers is liable to diffuse into adjacent ceramic layers. As a result, the ceramic layers of the drive portion may contain a base metal component of the internal electrode layers in addition to the inherent ceramic component.

On the other hand, the dummy portions do not include the internal electrode layers and are wholly composed of ceramic. Thus, a slight amount of the base metal component of the internal electrode layers of the drive portion diffuses into the dummy portions from the parts thereof in contact with the drive portion. As no base metal content diffuses from the dummy portions themselves, however, the base metal content of the dummy portions as a whole is very small as compared with that of the ceramic layers of the drive portion. At the time of sintering, therefore, the contraction ratio and the contraction behavior are different between the ceramic layers of the drive portion containing a base metal component and the dummy portions containing substantially no base metal component.

As a result, the neighborhood of the boundary area between the dummy portions and the drive portion can be deformed or may develop a gap.

### SUMMARY OF THE INVENTION

The prevent invention has been developed in view of these problems of the prior art, and the object thereof is to provide a piezoelectric element having a structure capable of suppressing deformation in the fabrication process.

According to a first aspect of the invention, there is provided a piezoelectric element comprising:

a drive portion including a plurality of ceramic layers composed of a piezoelectric ceramic and a plurality of internal electrode layers composed of a base metal, as the main component for supplying electricity to the ceramic layers, the ceramic layers and the internal electrode layers being stacked alternately; and

a dummy portion arranged at least on one of the end surfaces of the ceramic layers of the drive portion along the direction of stacking;

wherein the dummy portion is configured of ceramic and has at least a dummy electrode layer of the same material as the internal electrode layers.

In the piezoelectric element according to this aspect of the invention, the dummy portion has a dummy electrode layer. In the sintering step of the process for fabricating the piezoelectric element, therefore, the deformation which otherwise might be caused by the contraction difference between the dummy portion and the drive portion can be suppressed.

Specifically, the dummy portion has at least a dummy electrode layer as described above. The dummy electrode layer is composed of the same material as the internal electrode layers and contains the base metal component.

In the case where a stack of the dummy portion and the drive portion including the ceramic layers and the internal electrode layers stacked alternately is sintered for fabrication of a piezoelectric element, therefore, the base metal component of the internal electrode layers diffuses into the ceramic layers in the drive portion on the one hand, and the base metal portion of the dummy electrode layer diffuses into the ceramics of the dummy portion on the other hand. As a result, the ceramic layers of the drive portion and the ceramics of the dummy portion both come to contain the same base metal component, thereby reducing the contraction difference at the time of sintering.

In the piezoelectric element having a configuration according to this aspect of the invention, therefore, the deformation in the neighborhood of the boundary area between the dummy portion and the drive portion can be suppressed during the fabrication process.

According to a second aspect of the invention, there is provided a piezoelectric element comprising:

a drive portion including a plurality of ceramic layers composed of piezoelectric ceramics and a plurality of internal electrode layers composed of a base metal, as the main component for supplying electricity to the ceramic layers, the ceramic layers and the internal electrode layers being stacked alternately; and

a dummy portion arranged at least on one of the end surfaces of the ceramic layers of the drive portion along the direction of stacking;

wherein the thickness of the dummy portion is 0.1 to 1.5 times that of the ceramic layers of the drive portion.

In this aspect of the invention, the thickness of the dummy portion is limited to a small range of 0.1 to 1.5 times that of the ceramic layers as described above. During the fabrication process of the piezoelectric element, therefore, the stiffness of the dummy portion at the time of contraction is reduced during the sintering step. Further, in view of the small thickness of the dummy portion as a whole, the composition of the dummy portion is substantially equalized to that of the ceramic layers in the drive portion by a small amount of the base metal component diffusing from the drive portion. In the sintering step, therefore, the contraction difference between the dummy portion and the drive portion is reduced, or the contraction difference, if any, can be absorbed by the dummy portion having a small stiffness. Thus, the deformation in the neighborhood of the boundary area between the dummy portion and the drive portion can be suppressed.

As described above, the piezoelectric element having a configuration according to the invention can suppress the deformation in the neighborhood of the boundary between the dummy portion and the drive portion.

According to a third aspect of the invention, there is provided a piezoelectric element comprising:

a drive portion including a plurality of ceramic layers composed of piezoelectric ceramics and a plurality of internal electrode layers composed of a base metal as a main component for supplying electricity to the ceramic layers, the ceramic layers and the internal electrode layers being stacked alternately; and

a dummy portion arranged at least on one of the end surfaces of the ceramic layers of the drive portion along the direction of stacking;

wherein the dummy portion has such a composition that the base metal of the internal electrode layers is added to the component of the ceramic layers.

In this aspect of the invention, the dummy portion has such a composition that the base metal of the internal electrode layers is added to the component of the ceramic layers, as described above. At the time of sintering during the fabrication process of the piezoelectric element, therefore, the contraction difference between the dummy portion and the drive portion can be suppressed.

Specifically, during the sintering step, the base metal component of the internal electrode layers diffuses into the ceramic layers in the drive portion. On the other hand, the dummy portion contains the same base metal component as the internal electrode layers. As compared with the dummy portion containing no base metal component, therefore, the contraction behavior of the dummy portion containing the base metal component is more similar to that of the ceramic layers of the drive portion. Thus, the contraction difference is reduced between the drive portion and the dummy portion at the time of sintering. In this way, the deformation in the neighborhood of the boundary between the dummy portion and the drive portion can be suppressed.

As described above, in the piezoelectric element having a configuration according to this aspect of the invention, the deformation in the neighborhood of the boundary between the dummy portion and the drive portion can be suppressed during the fabrication process.

According to a fourth aspect of the invention, there is provided a piezoelectric element comprising a drive portion including a plurality of ceramic layers composed of piezoelectric ceramics and a plurality of internal electrode layers having a base metal as a main component for supplying electricity to the ceramic layers, the ceramic layers and the internal electrode layers being stacked alternately, wherein the internal electrode layers are arranged on the two end surfaces along the direction of stacking of the ceramic layers of the drive portion so that all the ceramic layers are expanded/contracted by the current supplied from the internal electrode layers.

The piezoelectric element according to this aspect of the invention comprises the drive portion alone and has no dummy portion. In the sintering step of the fabrication process of the piezoelectric element, therefore, the whole element is contracted substantially uniformly and the deformation thereof can be suppressed. In the case where the functions of the piezoelectric element require a dummy portion, such a dummy portion can be prepared and arranged separately as an independent member.

As a result, in the piezoelectric element according to this aspect of this invention having the configuration described above, the deformation during the fabrication process can be suppressed.

In the first to fourth aspects of the invention described above, the piezoelectric ceramic can be PZT (lead zirconate titanate), PZT plus other elements, barium titanate or other ceramics. The thickness of the piezoelectric ceramics is 50 to 150 μm, for example.

The ceramic of the dummy portion may or may not be formed of the same material as the ceramic layers.

The base metal making up a main component of the internal electrode layers is preferably a selected one of Ni, Cu, Fe and Cr or an alloy of any combination thereof. In such a case, a sufficient electrical conductivity can be secured while at the same time reducing the cost. Especially, the use of Cu which is inexpensive and widely used as an electrode material considerably contributes to a reduced cost of the piezoelectric element.

The thickness of the internal electrode layer is 1 to 10 μm, for example.

The drive portion is so configured that the ceramic layers and the internal electrode layers described above are stacked alternately, and the internal electrode layers are electrically connected to two different side electrodes alternately. Also, the drive portion is configured in such a manner as to expand/contract the ceramic layers by supplying current to the internal electrode layers.

The total volume of the piezoelectric element is preferably not less than 8 mm³. In the case where the total volume is less than 8 mm³, the deformation is liable to develop in the neighborhood of the boundary between the drive portion and the dummy portion which may be formed at the end of the drive portion during the fabrication process. Also in this case, the configuration according to the first to fourth aspects of the invention effectively suppresses the deformation.

The piezoelectric element is preferably an actuator. The actuator generates a strong force while repeating the expand/contract operation. The use of the piezoelectric element having the aforementioned configuration can suppress the deformation during the fabrication process and hence the cracking during the operation. Thus, the piezoelectric element can exhibit a superior durability also when used as an actuator.

Still another specific application is an actuator for operating the fuel injection valve of the engine fuel injector. The piezoelectric element for the injector is exposed to a very harsh operating condition and requires a high durability. Even in such a case, the piezoelectric element having the configuration described above can be effectively used.

In the second aspect of the invention described above, the dummy portion has a thickness larger than the thickness of the ceramic layer of the drive portion by a factor of 0.1 to 1.5. This produces a superior effect of operation. In the case where the thickness of the dummy portion is less than 0.1 times that of the ceramic layer, the dummy portion cannot exhibit a satisfactory effect of protecting the drive portion. In the case where the thickness of the dummy portion is more than 1.5 times that of the ceramic layer, on the other hand, the stiffness of the dummy portion is so high as to reduce the effect of suppressing the deformation at the time of sintering.

### BRIEF DESCRIPTION OF THE DRAWINGS

FIG. 1 is a diagram for explaining the structure of a piezoelectric element according to a first embodiment of the invention.

FIG. 2 is a diagram for explaining the structure of a unit element according to the first embodiment of the invention.

FIG. 3 is a diagram for explaining the structure of the dummy portion according to the first embodiment of the invention.

FIGS. 4a to 4f are diagrams for explaining a method of fabricating a piezoelectric element according to the first embodiment of the invention.

FIG. 5 is a development showing the arrangement of a ceramic laminate in the metallize process according to the first embodiment of the invention.

FIG. 6 is a diagram for explaining the arrangement of the ceramic laminate in a saggar during the metallizing process according to the first embodiment of the invention.

FIG. 7 is a diagram for explaining the arrangement of the ceramic laminate in a saggar during the sintering process according to the first embodiment of the invention.

FIG. 8 is a diagram for explaining the structure of a reduction sintering furnace used for the metallizing and sintering processes according to the first embodiment of the invention.

FIG. 9 is a diagram for explaining the sintering conditions according to the first embodiment of the invention.

FIGS. 10a and 10b are diagrams for explaining a malfunction according to a first comparison example.

FIG. 11 is a diagram for explaining another example of the structure of the dummy portion according to a second embodiment of the invention.

FIGS. 12a and 12b are diagrams for explaining another example of the structure of the lower and upper dummy portions, respectively, according to the second embodiment of the invention.

FIGS. 13a and 13b are diagrams for explaining the structure of the piezoelectric elements of samples 1 and 2, respectively, according to a third embodiment of the invention.

FIG. 14 is a development showing the arrangement of a ceramic laminate during the metallize process according to the third embodiment of the invention.

FIG. 15 is a diagram for explaining the structure of a piezoelectric element according to a fifth embodiment of the invention.

### DESCRIPTION OF THE PREFERRED EMBODIMENTS

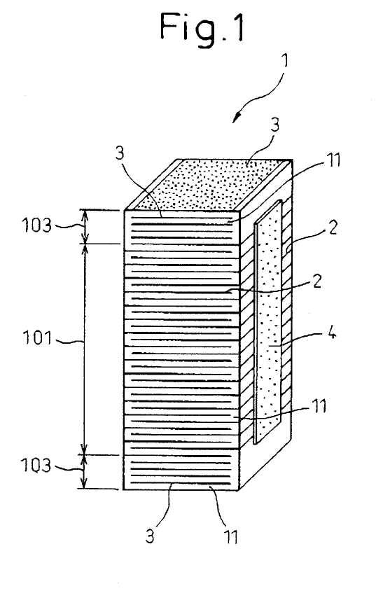

A piezoelectric element according to an embodiment of the invention will be explained with reference to FIGS. 1 to 9.

The piezoelectric element 1 according to an embodiment of the invention comprises, as shown in FIG. 1, a drive portion 101, and a dummy portion 103 arranged at each end surface, along the direction of stacking, of the ceramic layers 11 of the drive portion 101.

The drive portion 101 includes a plurality of ceramic layers 11 of piezoelectric ceramics and a plurality of internal electrode layers 2 containing a base metal as a main component for supplying electricity to the ceramic layers 11, the ceramic layers 11 and the internal electrode layers 2 being stacked alternately with each other.

The dummy portions 103 are each configured of ceramics and include a plurality of dummy electrode layers 3 of the same material as the internal electrode layers 2.

This structure will be explained in detail below.

The first step in fabricating the piezoelectric element 1 according to this embodiment is to prepare ceramic sheets constituting the base of the ceramic layers 11. The granulated powder adapted to have the desired PZT composition is prepared as a material of the ceramic sheets. First, 83.5 mol % lead oxide and 16.5 mol % tungsten oxide are weighted and mixed in dry state, after which the mixture is held and sintered at 500 to 700° C. for two hours, thereby producing assistant oxide powder with the lead oxide and the tungsten oxide partially reacted (expressed by the chemical formula PbO_{0.835}W_{0.163}O_{1.33}). This assistant oxide powder is improved in reactivity by being granulated and dried in a medium agitation mill.

As to the dielectric material, a provisionally sintered powder of a dielectric material is produced by dry mixing the dielectric components of PZT group and sintering it for 7 hours at 850° C., as described in Japanese Unexamined Patent Publication No. 8-183660. A mixture of 2.5 liters of water and a dispersant (2.5% of the weight of the powder) prepared in advance is gradually mixed with 4.7 kg of the provisionally sintered powder thereby to produce a provisionally sintered dielectric powder slurry. This provisionally sintered dielectric powder slurry is processed in the medium agitation mill, and the particle size is controlled to not more than 0.2 μm in the pearl mill.

To the provisionally sintered dielectric powder slurry having a particle size of not more than 0.2 μm, 4 wt. % of a binder and 1.9 wt. % of a releasing agent are added. Further, 13.5 g of the mixture (0.5 atm. % of PbO_{0.835}W_{0.165}O_{1.33}) is mixed with 1600 g of the provisionally sintered dielectric powder and, after being agitated for three hours, dried using the spray dryer thereby to produce the granulated powder of the provisionally sintered dielectric powder.

Using this granulated powder, a slurry is prepared and it is formed into a sheet having a thickness of 125 μm, before drying, by the doctor blade method.

After drying at 80° C., the sheet is cut into the size of 100 mm×150 mm by sheet cutter thereby to produce a ceramic sheet.

In order to use Cu for the internal electrode layers 2 according to this embodiment, a paste having a CuO base is prepared as an electrode paste. More specifically, a CuO paste of 1.8 g having the CuO contents of 50 wt. % and the CuO specific surface area of 10 m²/g is mixed with Cu powder (1050YP of Mitsui Metal) of 1.11 g and provisionally sintered dielectric powder of 0.09 g, after which the mixture is processed in the centrifugal agitation deaerator thereby to prepare an electrode paste.

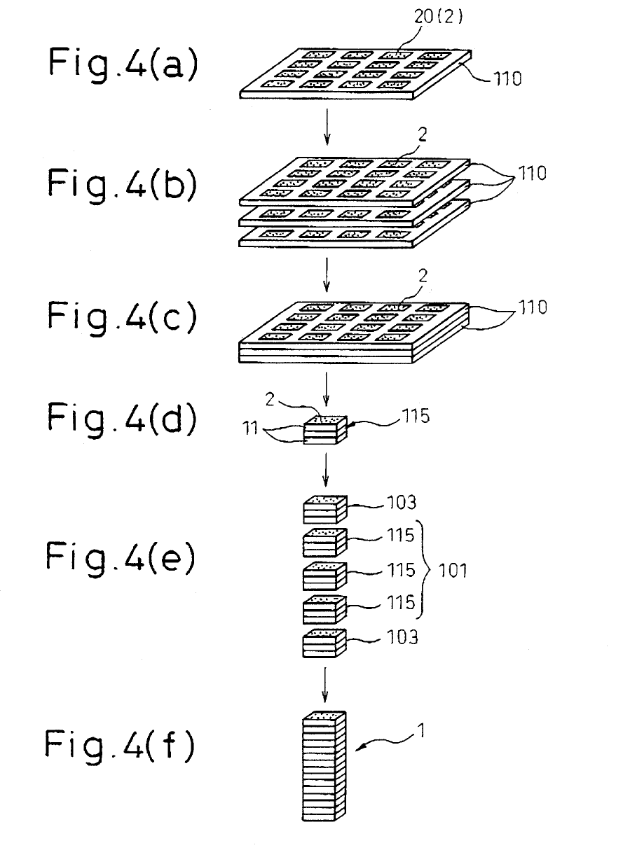

As shown in FIG. 4a, the surface of a ceramic sheet 110 is printed with electrode pastes constituting internal electrode layers 2 by the screen printer. The print thickness is 5 to 8 μm. The electrode pastes, after being printed, are dried at 130° C. for one hour. In FIG. 4(a), the electrode paste is shown as an internal electrode layer 2.

As shown in FIGS. 4b, 4c, 20 ceramic sheets 110, having the internal electrode layers 2, are stacked and thermally bonded at 120° C. for ten minutes under a pressure of 80 kg/m² to thereby produce a mother block.

As shown in FIG. 4d, the mother block is cut into pieces each having the size of 9 mm×9 mm thereby to produce unit elements 115.

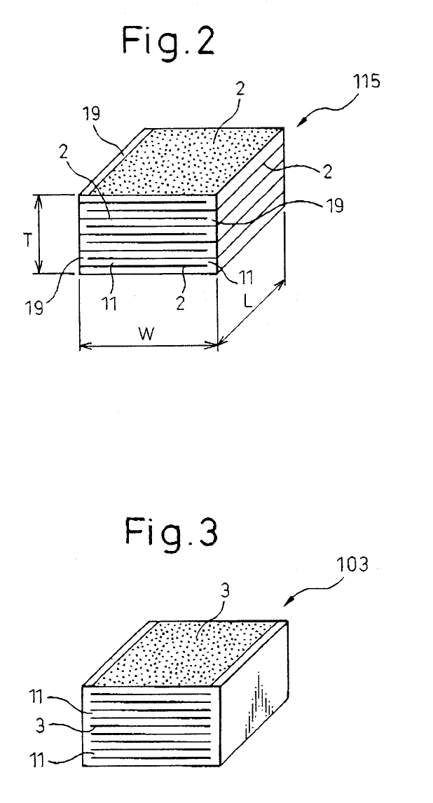

The unit element 115 thus obtained is shown in FIG. 2. As shown in FIG. 2, each unit element 115 includes the ceramic layers 11 and the internal electrode layers 2 stacked alternately thereby to form a laminate having the width W of 9 mm, the length L of 9 mm and the thickness T of 2 mm. The alternate ones of the internal electrode layers 2 are staggered laterally and each have a bracing portion 19 not covered by the ceramic layers 11.

According to this embodiment, a dummy portion 103 is prepared by substantially the same steps as for preparing the unit element 115.

Specifically, in the above-mentioned screen printing process, the area for printing the electrode pastes is slightly reduced to form a dummy electrode layer 3. Specifically, as shown in FIG. 3, the dummy portion 103 is configured of the same ceramic layers 11 as those of the drive portion and the dummy electrode layers 3 stacked alternately. Each dummy electrode layer 3 is provided with left and right bracing portions 19. The thermal bonding and other conditions are the same as those for preparing the unit element 115.

As shown in FIG. 4e, a plurality of the unit elements 115 are stacked to form the drive portion 101, while at the same time stacking the dummy portions 103 on the upper and lower surfaces of the drive portion, respectively, followed by the thermal bonding process. The thermal bonding is carried out at 80° C. for ten minutes under the pressure of 500 kg/m². After the thermal bonding process, a ceramic laminate 10 having the size of 9 mm by 9 mm by 40 mm is obtained.

According to this embodiment, the next step is to decrease the major portion of the binder resin contained in the ceramic of the ceramic laminate. Specifically, a mgO plate (15 mm by 15 mm) having the porosity of 20% is placed above and under the ceramic laminate and heated in the atmosphere to perform a degrease operation. The heating conditions involved are such that the set heating temperature is increased at intervals of 20 hours, until finally the temperature of 500° C. is held for five hours,

In a sufficiently ventilated environment where the uniform heating is possible, a different processing method and conditions can be employed.

According to this embodiment, the CuO of the internal electrode layers 2 is reduced to Cu (metallizing process).

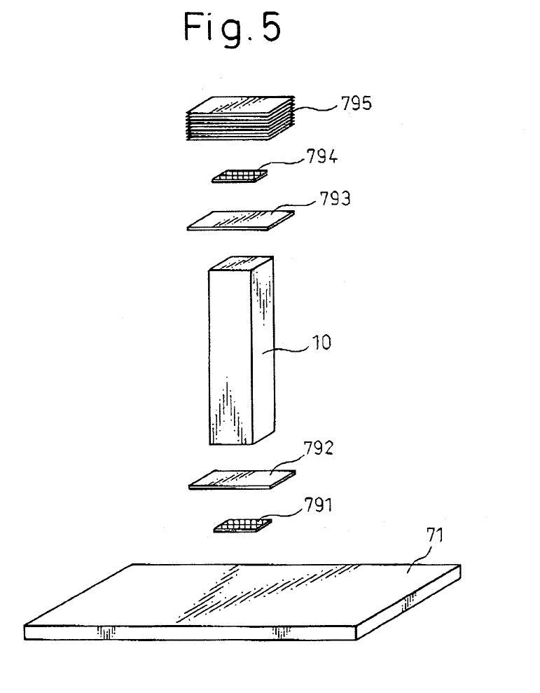

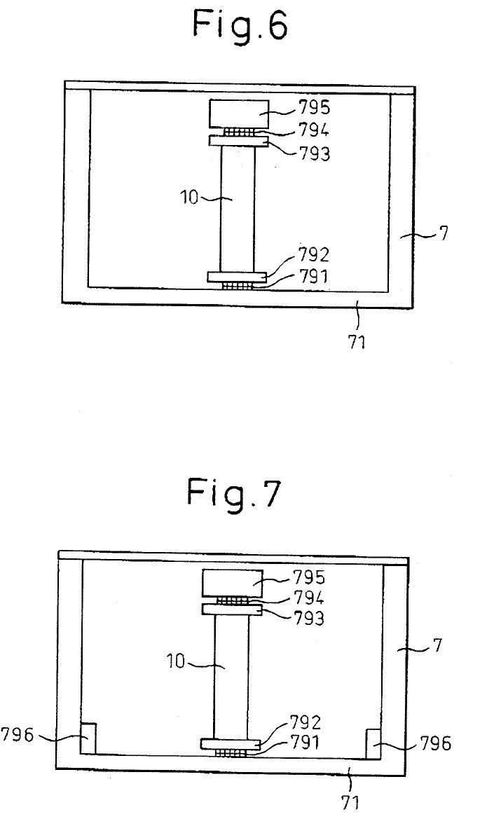

Specifically, as shown in FIGS. 5 and 6, the degreased ceramic laminate 10 is placed and heated in a saggar 7. An alumina honeycomb 791, a MgO plate 792, a ceramic laminate 10, a MgO plate 793, an alumina honeycomb 794 and a MgO weight 795 are stacked in that order on the bottom in the saggar 7.

The saggar 7 is placed and heat treated in a reduction environment containing 5000 ml of Ar with 1% H₂, and 6.5 ml of pure O₂ in accordance with a heating pattern where the temperature is gradually increased to about 350° C. over four hours and held at 325 to 400° C. for 12 hours. After that, the temperature is gradually decreased to room temperature in about four hours. The oxygen environment held at a high temperature is controlled in such a manner that the value P of the “external oxygen partial pressure” is in the range of 1×10⁻¹⁴ to 1×10^{-24.7} as analyzed midway in the gas discharge path.

This metallizing process reduces the base metal Cu of the internal electrode layers 2 from oxide to metal for the first time.

According to this embodiment, the next step is the sintering in the reduction environment.

Also in this sintering step, the saggar 7 is used with the same arrangement as in the metallizing process. Further, as shown in FIG. 7, in the sintering step, a PbZrO. lump 796 is placed at four corners of the saggar 7 for preventing the PbO from evaporating off from the ceramic laminate 10 at high temperatures.

The saggar 7 is heated in a reduction environment using Co₂—CO—O₂ gas, and by thus sintering the ceramic laminate 10, a piezoelectric element 1 is produced.

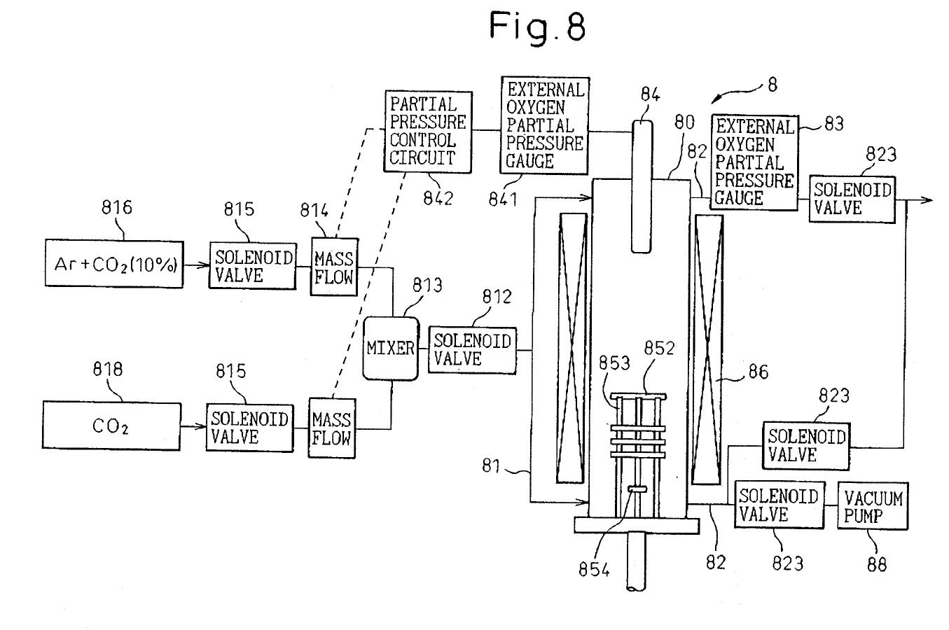

The reduction sintering furnace 8 used in this embodiment is shown in FIG. 8. The reduction sintering furnace 8 can be used also for the metallizing process described above.

As shown in FIG. 8, the reduction sintering furnace 8 is connected with a gas introduction path 18 for introducing the atmospheric gas into the furnace body 80. The gas introduction path 81 is connected to two gas sources 816, 818 through a solenoid valve 812, a mixer 813, two master flows 814 and two solenoid valves 815, respectively.

The furnace body 80 can be switched by the three solenoid valves 823 between a path for discharging the atmospheric gas and a path to a vacuum pump 88 for vacuuming the interior of the furnace. An external oxygen partial pressure gauge 83 is arranged midway in the gas discharge path 82.

An internal oxygen partial pressure sensor 84 is inserted in the furnace body 80 and connected to an internal oxygen partial pressure gauge 841 and a partial pressure control circuit 842. The partial pressure control circuit 842 is connected to and controls the master flow 814 in the gas introduction path 81.

A sample sintering stage 852, a stage support member 853 and a gas agitation fan 854 are arranged in the furnace body 80. A heater 86 is arranged around the furnace body 80.

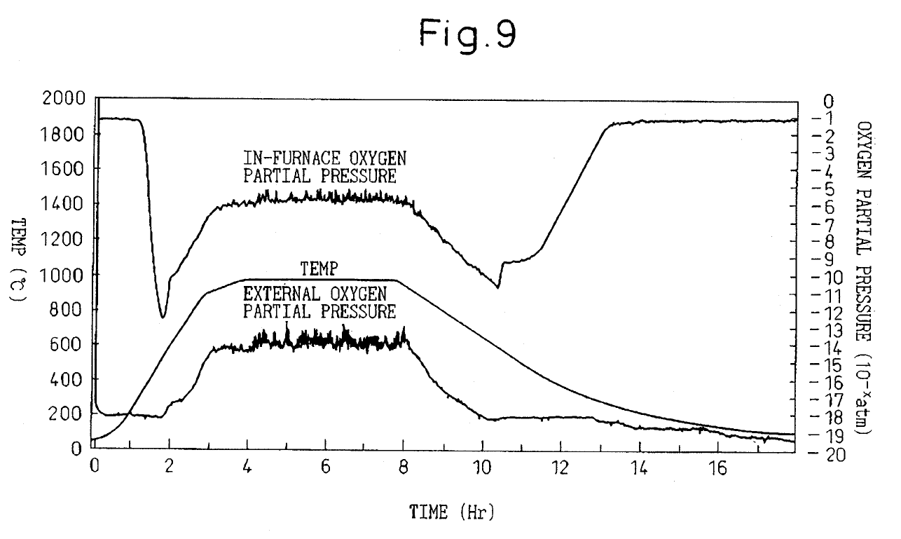

According to this embodiment, the reduction sintering process is carried out under the conditions shown in FIG. 9 using an atmospheric gas of CO₂—CO—O₂ with the reduction sintering furnace 8 described above. In FIG. 9, the abscissa represents the time (Hr), and the coordinate the temperature (° C.) and the oxygen partial pressure (X of 10^{-x} atm). As shown in FIG. 9, the temperature is gradually increased and held at 950° C., followed by being decreased gradually. As a result, a sufficiently low oxygen partial pressure can be maintained, thereby making it possible to maintain the copper of the internal electrode layers 2 and the dummy electrode layers 3 in the metal phase.

In the sintering process, the copper making up the base metal component of the internal electrode layers 2 in the form of CuO is diffused into the ceramic layers 11, for example. In the dummy portion 103, on the other hand, the copper making up the base metal portion of the dummy electrode layers 3 is diffused in the ceramic layers 11. As a result, the difference in contraction behavior is reduced between the dummy portion 103 and the drive portion 101 at the time of sintering. Thus, the deformation in the neighborhood of the boundary between the dummy portion 103 and the drive portion 101 can be suppressed, thereby producing a piezoelectric element 1 having a preferable profile.

This piezoelectric element 1 can exhibit a high durability when used as an actuator.

In actual use, the piezoelectric element 1 has, as shown in FIG. 1, a side electrode 4 arranged and connected with an external electrode or the like for supplying current.

The piezoelectric element, which is in the shape of a square pole in the first embodiment, may alternatively have a circular, elliptical, barrel-shaped, hexagonal, octagonal or the like section.

All these points are similar to the corresponding points of all the embodiments described below.

(Comparison Example)

In this example, the dummy portion 103 according to the first embodiment is replaced by 20 ceramic layers 11 without the dummy electrode layer 3. The other points are similar to the corresponding points of the first embodiment.

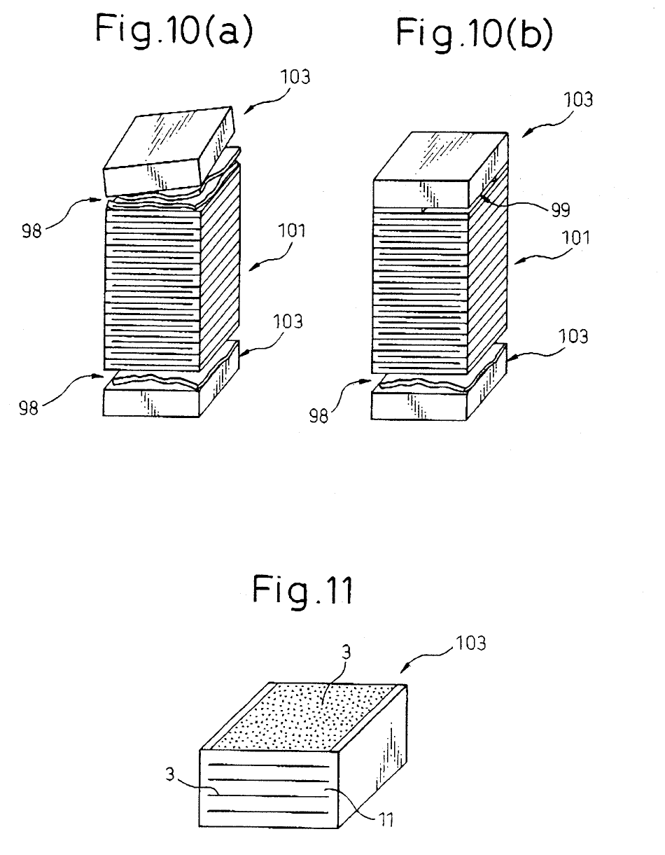

In this case, as shown in FIGS. 10a, 10b, a deformation 98 or a gap (crack) 99 develops in the neighborhood of the boundary between the drive portion 101 and the dummy portion 103 of the piezoelectric element.

This phenomenon itself indicates that the piezoelectric element 1 according to the first embodiment has a superior configuration.

(Second Embodiment)

According to this embodiment, the dummy portion 103 of the first embodiment is replaced by a dummy portion having a different structure.

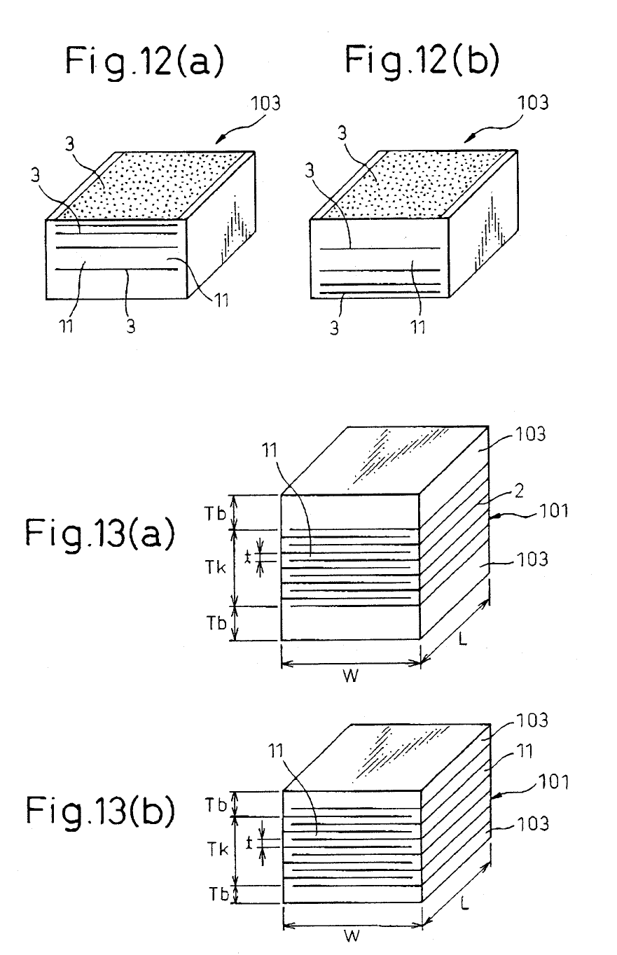

FIGS. 11 and FIGS. 12a, 12b show examples of the dummy portion according to this embodiment.

The dummy portion 103 shown in FIG. 11 has dummy electrode layers 3 one half less than the first embodiment, with an interval twice as large.

The dummy portion 103 shown in FIGS. 12a, 12b, on the other hand, is an example in which the dummy electrode layers 3 are built in at a pitch progressively decreased toward the drive portion 101.

The unit element 115 for the drive portion 101 shown in FIG. 2 can be used as it is as a dummy portion 103. In such a case, the internal electrode layers 2 of the unit element 115 used as a dummy portion 103 constitute the dummy electrode layers 3 not supplied with current.

The use of these dummy portions 103 can produce the same function and effect as the first embodiment.

(Third Embodiment)

In this embodiment, as shown in FIGS. 13a, 13b, only one set of the unit elements 115 according to the first embodiment are used to constitute the drive portion 101. Above and under the drive portion 101, the dummy portion 103 of the same ceramic as the ceramic layers 11 of the drive portion 101 is arranged thereby to prepare samples 1 and 2. The effect of the thickness difference of the dummy portion 103 was studied.

In sample 1 shown in FIG. 13a, the thickness Td of the dummy portion 103 is 0.3 mm which is 2.4 times as large as the thickness t of the ceramic layers 11 of the drive portion 101.

The dummy portion 103 of sample 2 shown in FIG. 13b, on the other hand, has a thickness Td of 0.15 mm, which is 1.2 times as large as the thickness of the ceramic layer 11 of the drive portion 101.

Both samples 1 and 2 have the same width w of 9 mm and the same length L of 9 mm. The thickness Tk of the drive portion 101 is 2 mm for both the samples.

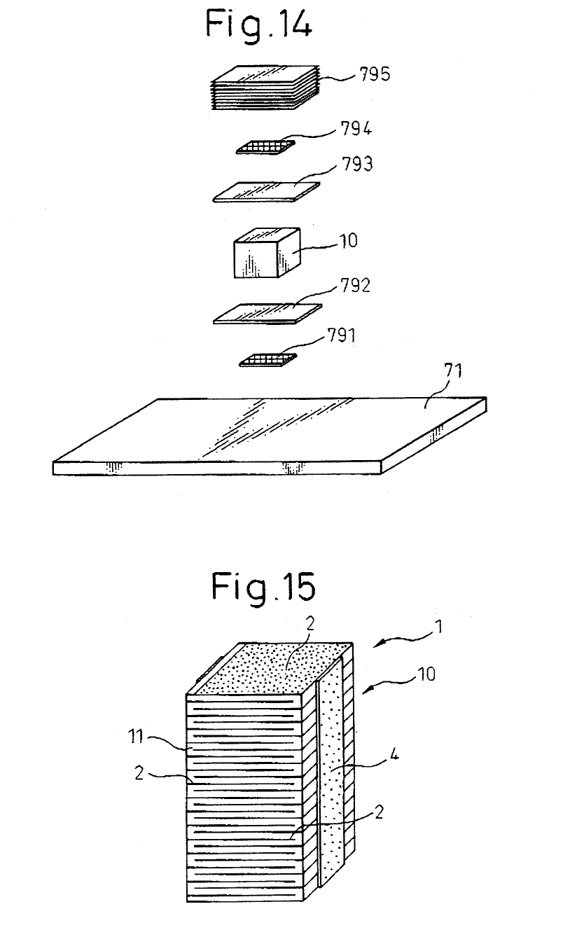

In order to fabricate a piezoelectric element having this configuration, the fabrication process similar to that of the first embodiment is carried out. Also in the metallizing and sintering processes, the piezoelectric element (ceramic laminate 10) is mounted in a similar manner to the first embodiment as shown in FIG. 14. Specifically, an alumina honeycomb 791, a MgO plate 792, a ceramic laminate 10, a MgO plate 793, an alumina honeycomb 794 and a MgO weight 795 are stacked in that order on the bottom portion 71 of the saggar 7.

The observation of the piezoelectric element thus obtained shows that sample 1 with the dummy portion thickness Td not less than 2.4 times (over 1.5 times) as large as the thickness of the ceramic layer 11 is deformed slightly in the neighborhood of the boundary between the dummy portion 103 and the drive portion 101. Sample 2 of which the dummy portion has a thickness Td not more than 1.2 times (not more than 1.5 times) as large as that of the ceramic layers 11, on the other hand, is generally not deformed and is finished in a satisfactory fashion.

This indicates that the deformation at the time of sintering can be prevented by setting the thickness of the dummy portion 102 as a whole to not more than 1.5 times as large as the thickness of the ceramic layer 11 of the drive portion 101.

(Fourth Embodiment)

This embodiment represents an example in which the dummy portion 103 has the same composition as the component of the ceramic layer 11 with the base metal Cu of the internal electrode layer 2 added thereto. The dummy portion 103 is not provided with the dummy electrode layer. The other points are similar to the corresponding points of the first embodiment.

In this case, the piezoelectric element fabricated in the same way as in the first embodiment develops substantially no deformation in the neighborhood of the boundary between the dummy portion 103 and the drive portion 101.

This is probably due to the fact that since the dummy portion 103 originally contains the base metal component, the composition thereof approaches that of the ceramic layer 11 of the drive portion 101 at the time of sintering. As a result, the contraction difference between the drive portion 101 and the dummy portion 102 is reduced at the time of sintering, thereby suppressing the deformation in the neighborhood of the boundary between them.

Also, according to this embodiment, in order to reduce the contraction difference between the dummy portion 103 and the drive portion 101 at the time of sintering, a base metal component is added to the ceramics of the dummy portion 103. As an alternative method, the contraction behavior is changed by changing the composition of PZT making up the dummy portion, or by changing the density of the ceramic sheet made of ceramic.

(Fifth Embodiment)

This embodiment represents a case in which a piezoelectric element 1 wholly comprises the drive portion 101 and has no dummy portion.

Specifically, as shown in FIG. 15, the piezoelectric element 1 according to this embodiment comprises a drive portion 101 including a plurality of ceramic layers 11 of piezoelectric ceramics and a plurality of internal electrode layers 2 having the base metal Cu as a main component for supplying electricity to the ceramic layers 11, wherein the ceramic layers 11 and the internal electrode layers 2 are stacked alternately. The two end surfaces, along the direction of stacking, of the ceramic layers 11 of the drive portion 101 are each formed with an internal electrode layer 2, so that all the ceramic layers 11 are expanded/contracted by the current supplied from the internal electrode layers 2.

The other points are similar to the corresponding points of the first embodiment except that this embodiment has no dummy portion.

The laminate member of the piezoelectric element according to this embodiment, as described above, has no dummy portion but only the drive portion 110. In the sintering step for fabrication of the piezoelectric element 1, therefore, the whole element is contracted substantially uniformly and the deformation can be suppressed. In the case where the functions of the piezoelectric element 1 requires a dummy portion, it can be prepared and arranged as a separate member.

In the piezoelectric element 1 having the above-mentioned configuration, therefore, the deformation during the fabrication process can be suppressed.

What is claimed is:

1. A piezoelectric element comprising:
a drive portion including a plurality of ceramic layers composed of a piezoelectric ceramic and a plurality of internal electrode layers composed of a base metal as a main component for supplying electricity to said ceramic layers, said ceramic layers and said internal electrode layers being stacked alternately; and
a dummy portion arranged at least on one of the end surfaces of the ceramic layers of the drive portion along the direction of stacking;
wherein said dummy portion is configured of ceramic and has at least a dummy electrode layer of the same material as the internal electrode layers.

2. A piezoelectric element according to claim 1,
wherein the base metal making up a main component of said internal electrode layers is a selected one of Ni, Cu, Fe and Cr and an alloy of any combination thereof.

3. A piezoelectric element according to claim 1,
wherein the whole of said piezoelectric element has a volume of not less than 8 mm³.

4. A piezoelectric element according to claim 1,
wherein said piezoelectric element is an actuator.

5. A piezoelectric element comprising:
a drive portion including a plurality of ceramic layers composed of piezoelectric ceramics and a plurality of internal electrode layers composed of a base metal as a main component for supplying electricity to said ceramic layers, said ceramic layers and said internal electrode layers being stacked alternately; and
a dummy portion arranged at least on one of the end surfaces of said ceramic layers of the drive portion along the direction of stacking;
wherein the thickness of said dummy portion is in the range of 0.1 to 15 times that of the ceramic layers of said drive portion.

6. A piezoelectric element according to claim 5,
wherein the base metal making up a main component of said internal electrode layers is selected one of Ni, Cu, Fe and Cr and an alloy of any combination thereof.

7. A piezoelectric element according to claim 5,
wherein the whole of said piezoelectric element has a volume of not less than 8 mm³.

8. A piezoelectric element according to claim 5,
wherein said piezoelectric element is an actuator.

9. A piezoelectric element comprising:
a drive portion including a plurality of ceramic layers composed of a piezoelectric ceramic and a plurality of internal electrode layers composed of a base metal as a main component for supplying electricity to said ceramic layers, said ceramic layers and said internal electrode layers being stacked alternately; and
a dummy portion arranged at least on one of the end surfaces of said ceramic layers of the drive portion along the direction of stacking;
wherein said dummy portion has such a composition that the base metal of the internal electrode layers is added to the component of said ceramic layers.

10. A piezoelectric element according to claim 9,
wherein the base metal making up a main component of said internal electrode layers is selected one of Ni, Cu, Fe and Cr and an alloy of any combination thereof.

11. A piezoelectric element according to claim 9,
wherein the whole of said piezoelectric element has a volume of not less than 8 mm³.

12. A piezoelectric element according to claim 9,
wherein said piezoelectric element is an actuator.

13. A piezoelectric element comprising a drive portion including a plurality of ceramic layers composed of a piezoelectric ceramic and a plurality of internal electrode layers having a base metal as a component for supplying electricity to the ceramic layers, said ceramic layers and said internal electrode layers being stacked alternately, wherein said internal electrode layers are arranged on the two end surfaces along the direction of stacking of said ceramic layers of said drive portion so that all the ceramic layers are expanded/contracted by the current supplied from said internal electrode layers.

14. A piezoelectric element according to claim 13,
wherein the base metal making up a main component of said internal electrode layers is selected one of Ni, Cu, Fe and Cr and an alloy of any combination thereof.

15. A piezoelectric element according to claim 13,
wherein the whole of said piezoelectric element has a volume of not less than 8 mm³.

16. A piezoelectric element according to claim 13,
wherein said piezoelectric element is an actuator.
